(19) United States
(12) Patent Application Publication
(10) Pub. No.: US 2016/0268275 A1
(43) Pub. Date: Sep. 15, 2016

(54) NON-VOLATILE MEMORY DEVICE AND METHOD FOR MANUFACTURING THE SAME

(71) Applicant: Kabushiki Kaisha Toshiba, Minato-ku (JP)

(72) Inventors: Yuta WATANABE, Yokkaichi (JP); Takeshi ISHIZAKI, Nagoya (JP); Kana HIRAYAMA, Yokkaichi (JP); Kenji AOYAMA, Yokkaichi (JP)

(73) Assignee: Kabushiki Kaisha Toshiba, Minato-ku (JP)

(21) Appl. No.: 14/837,306

(22) Filed: Aug. 27, 2015

Related U.S. Application Data
(60) Provisional application No. 62/132,747, filed on Mar. 13, 2015.

(51) Int. Cl. H01L 27/115

(52) U.S. Cl. CPC H01L 27/11521

(57) ABSTRACT

A non-volatile memory device includes a first semiconductor body extending in a first direction, an electrode extending in a second direction intersecting the first direction, a charge storage layer provided between the first semiconductor body and the electrode, and a first insulating layer provided between the electrode and the charge storage layer. The electrode includes a first layer, a second layer and a third layer. The first layer is provided on the first insulating layer and includes tungsten. The second layer is provided on the first layer and includes tungsten nitride. The third layer is provided on the second layer and includes tungsten.

### CROSS-REFERENCE TO RELATED APPLICATIONS

This application is based upon and claims the benefit of priority from U.S. Provisional Patent Application 62/132,747 filed on Mar. 13, 2015; the entire contents of which are incorporated herein by reference.

### FIELD

Embodiments described herein relate generally to a non-volatile memory device and a method for manufacturing the same.

### BACKGROUND

A non-volatile memory device includes memory cells that are highly integrated; and interconnects that electrically connect the memory cells to peripheral circuits also are downscaled to match the size of the memory cells. Therefore, even in the case where metal is included in the interconnects of the memory cells, the operation speed of the memory cells may decrease due to the interconnect resistance of the interconnects. Accordingly, an interconnect structure is necessary in which it is possible to reduce the interconnect resistance.

### BRIEF DESCRIPTION OF THE DRAWINGS

FIGS. 1A and 1B are schematic plan views showing a non-volatile memory device according to an embodiment;

FIG. 2 is a schematic cross-sectional view showing a memory cell of the non-volatile memory device according to the embodiment;

FIGS. 3A to 8B are schematic cross-sectional views showing a manufacturing processes of the non-volatile memory device according to the embodiment;

FIGS. 9A to 10B are SEM images (Scanning Electron Microscope Image) of electrodes according to the embodiment;

FIGS. 11A and 11B are SEM images of an electrode according to a comparative example; and

FIG. 12 shows the characteristics of a non-volatile memory device according to the comparative example.

### DETAILED DESCRIPTION

According to one embodiment, a non-volatile memory device includes a first semiconductor body extending in a first direction, an electrode extending in a second direction intersecting the first direction, a charge storage layer provided between the first semiconductor body and the electrode, and a first insulating layer provided between the electrode and the charge storage layer. The electrode includes a first layer, a second layer and a third layer. The first layer is provided on the first insulating layer and includes tungsten. The second layer is provided on the first layer and includes tungsten nitride. The third layer is provided on the second layer and includes tungsten.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

### First Embodiment

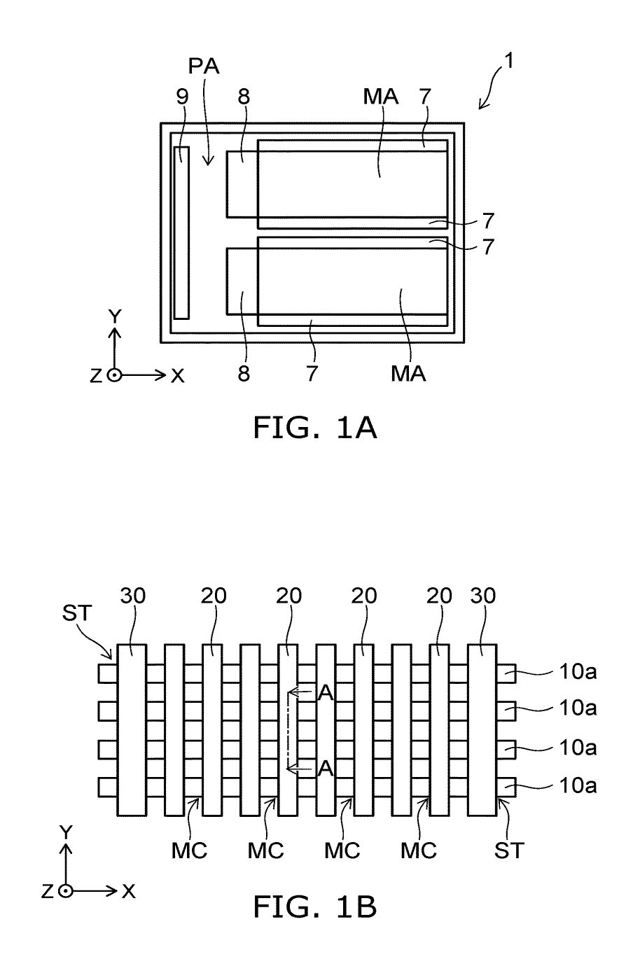

FIGS. 1A and 1B are schematic plan views showing a non-volatile memory device 1 according to a first embodiment. FIG. 1A is a schematic view showing a chip surface of the non-volatile memory device 1. FIG. 1B is a schematic view showing the arrangement of memory cells MC.

The non-volatile memory device 1 is, for example, NAND flash memory. As shown in FIG. 1A, the non-volatile memory device 1 includes a memory region MA, and a peripheral region PA provided around the memory region MA. The memory region MA includes the multiple memory cells MC. The peripheral region PA includes peripheral circuits such as a row decoder 7, a sense amplifier 8, etc. Also, a connection region 9 is provided in the peripheral region PA. The connection region 9 includes pads for electrically connecting the peripheral circuits to external terminals (not shown).

As shown in FIG. 1B, multiple semiconductor bodies 10a are provided in the memory region MA. Each of the semiconductor bodies 10a extends in a first direction (hereinbelow, an X-direction). The semiconductor bodies 10a are arranged in a second direction (hereinbelow, a Y-direction) intersecting the first direction.

Multiple electrodes 20 are provided in the memory region MA. The electrodes 20 are, for example, word lines extending in the Y-direction on the multiple semiconductor bodies 10a. The memory cells MC are provided respectively at the intersections between the semiconductor bodies 10a and the electrodes 20. The semiconductor bodies 10a form the channels of the memory cells MC.

As shown in FIG. 1B, the electrodes 20 are arranged in the X-direction. Also, selection gates 30 are disposed respectively at two sides of the multiple electrodes 20 arranged in the X-direction. The selection gates 30 extend in the Y-direction on the multiple semiconductor bodies 10a. Selection transistors ST are provided at the intersections between the semiconductor bodies 10a and the selection gates 30. In other words, the multiple memory cells MC are arranged in the X-direction on the semiconductor body 10a. Also, the selection transistors ST are disposed respectively at two sides of the multiple memory cells MC arranged in the X-direction.

For example, the semiconductor bodies 10a are electrically connected to the sense amplifier 8 via not-shown bit lines and source lines. For example, the electrodes 20 and the selection gates 30 are electrically connected to the row decoder 7. The row decoder 7 controls, via the selection transistors ST, the ON/OFF of the electrical conduction between the semiconductor body 10a and the bit line and between the semiconductor body 10a and the source line.

For example, the row decoder 7 causes, via the selection transistors ST, the semiconductor body 10a and the sense amplifier 8 to be electrically connected and selectively applies, via the electrodes 20, voltages to the memory cells MC. Thereby, data can be programmed to the selected memory cell. Also, the sense amplifier 8 can read the data stored in the selected memory cell MC.

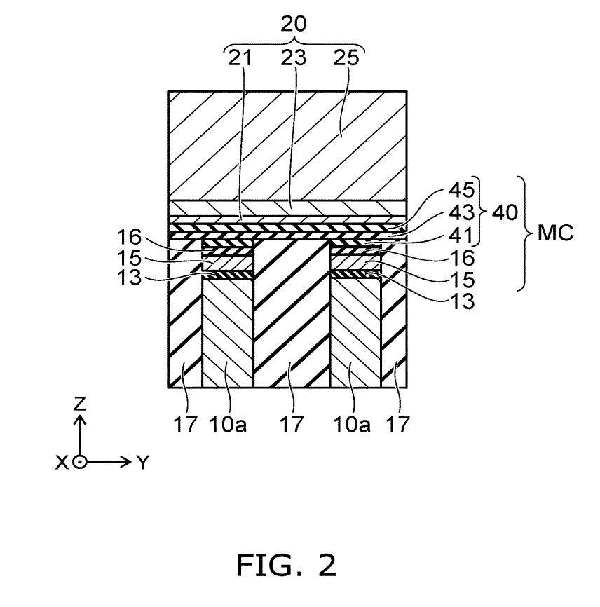

The structure of the memory cell MC of the non-volatile memory device 1 will now be described with reference to FIG. 2. FIG. 2 is a schematic view showing a cross section along line A-A shown in FIG. 1B.

As shown in FIG. 2, the memory cell MC is provided between the semiconductor body 10a and the electrode 20. The memory cell MC includes an insulating layer 13, a charge storage layer 15, an insulating layer 16, and an insulating layer 40. The insulating layer 13 functions, for example, as a so-called tunneling insulating layer between the semiconductor body 10a and the charge storage layer 15. The charge storage layer 15 is made of a polysilicon layer that is included in a floating gate electrode. The insulating layer 16 is formed on the upper surface of the charge storage layer 15 and is, for example, a silicon nitride layer or a silicon oxynitride layer. The insulating layer 40 functions as a so-called insulative blocking layer between the charge storage layer 15 and the electrode 20.

STI (Shallow Trench Isolation) 17 is provided between the memory cells MC adjacent to each other in the Y-direction. The STI 17 electrically isolates the semiconductor bodies 10a adjacent to each other in the Y-direction and electrically insulates the memory cells MC adjacent to each other in the Y-direction.

The insulating layer 40 includes, for example, a first layer 41 that is provided on the insulating layer 16, a second layer 43 that is provided on the first layer 41, and a third layer 45 that is provided on the second layer 43. The first layers 41 are provided to be separated from each other on the charge storage 15. The first layer 41 is, for example, a metal oxide layer such as hafnium silicate (HfSiO), etc. The second layer 41 is an insulating layer including silicon. The third layer 45 is, for example, a metal oxide layer of hafnium silicate, etc.

Also, the first layer 41 can store charge that is injected by passing through the insulating layer 16. Accordingly, the layers including the charge storage layer 15 to the insulating layer 16 and the first layer 41 can be called the charge storage layer. Thereby, the stored charge amount can be increased; and the threshold voltage can be set to be high. For example, such a configuration is advantageous for multi-bit memory cells MC.

The second layer 43 and the third layer 45 extend in the Y-direction along the electrode 20. In other words, the second layer 43 and the third layer 45 are interposed between the electrode 20 and the STI 17. Also, the upper surface of the STI 17 is positioned at a level higher than the upper surface of the charge storage layer 15 and is positioned at the same level as the upper surface of the first layer 41.

The electrode 20 has a three-layer structure including a first layer 21, a second layer 23, and a third layer 25. The first layer 21 is provided on the insulating layer 40 and includes tungsten (W). The first layer 21 is, for example, a tungsten layer or a tungsten nitride (WN) layer. The second layer 23 is, for example, a tungsten nitride layer. The tungsten nitride included in the second layer 23 has a first composition ratio. The tungsten nitride included in the first layer 21 has a second composition ratio that has a smaller proportion of nitrogen atoms than the first composition ratio. The third layer 25 is, for example, a tungsten layer. In the embodiment, by using the electrode 20 having such a structure, the electrical resistance of the electrode 20 is reduced.

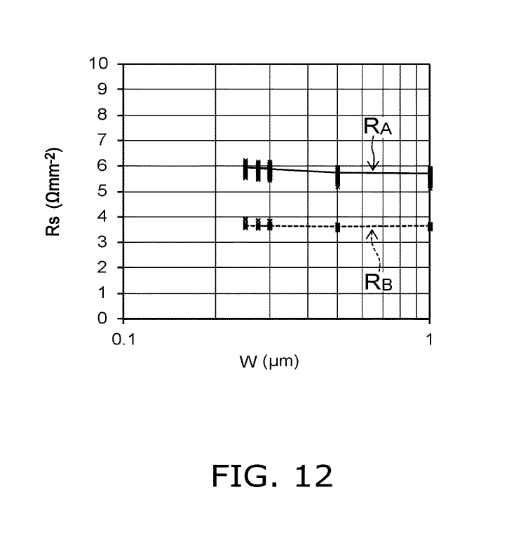

For example, FIG. 12 shows the interconnect resistance of a non-volatile memory device according to a comparative example. The horizontal axis is an interconnect width W (μm). The vertical axis is a sheet resistance Rs (Ω/□) of the interconnect layer. R_{A} shown in FIG. 12 illustrates the sheet resistance of a tungsten layer formed on a hafnium silicate. R_{B} illustrates the sheet resistance of a tungsten layer formed on polysilicon.

As shown in FIG. 12, the sheet resistance of the tungsten layer R_{A} formed on hafnium silicate is 5.7 to 5.9Ω/□ for an interconnect width of 0.25 to 1.0 micrometers (μm). On the other hand, the sheet resistance R_{B} of the tungsten layer formed on polysilicon is 3.3 to 3.7Ω/□.

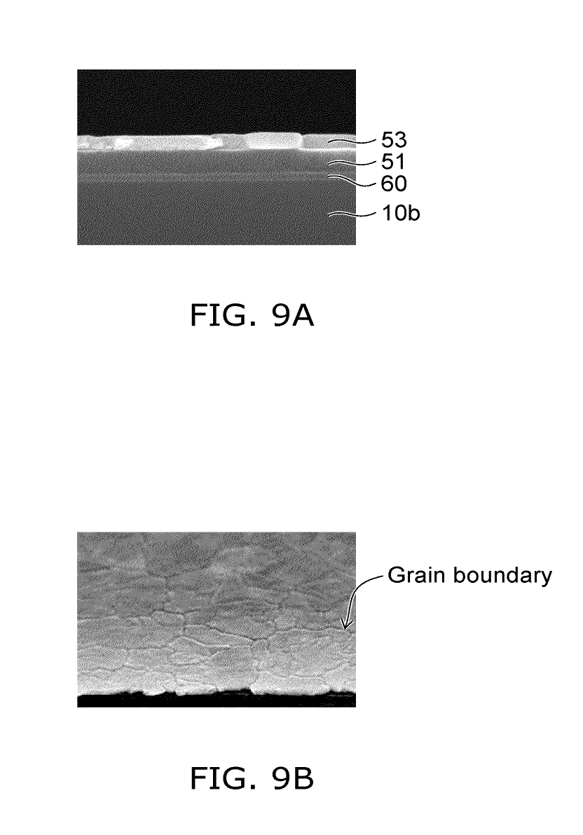

For example, a tungsten layer that is formed using sputtering is an aggregate of multiple tungsten particles. Then, the sheet resistance of the tungsten layer decreases as the particle size of the tungsten particles increases. The average particle size of tungsten particles formed on polysilicon is about 3.6 times the average particle size of tungsten particles formed on hafnium silicate. Accordingly, the sheet resistance R_{A} shown in FIG. 9 is about 1.6 times the sheet resistance R_{B}.

For example, there is a tendency for the grain size of a tungsten layer formed on a metal oxide layer to be dependent on the crystal orientation of the foundation and to be small. Accordingly, the resistance of an interconnect formed on a metal oxide layer is large compared to the resistance of an interconnect formed on a polysilicon or silicon oxide layer. On the other hand, it is desirable for a metal oxide layer to be included in at least a portion of the insulating layer 40 to reduce the leakage current of the blocking insulating layer in the memory cell MC.

The electrode 20 of the embodiment has a stacked structure including the first layer 21 and the second layer 23 that are provided on the insulating layers, and the third layer 25 that functions as an interconnect. For example, the first layer 21 and the second layer 23 shield the effect of the crystal orientation of the metal oxide layer and increase the grain size of the third layer 25. Thereby, the resistance of the third layer 25 can be reduced.

The characteristics of the electrode 20 are shown in Table 1. These samples 1 to 6 are formed using sputtering on the insulating layer 40 including hafnium silicate.

TABLE 1

| SNo. | Electrode structure | Tcf (nm) | R (Ωmm−2) | Vinv (V) |
|---|---|---|---|---|
| I | W1/WN1/W2 | 1.5 | 2.6 | −7 |
| 2 | W1/WN1/W2 | 3.0 | 2.8 | −4.7 |
| 3 | WN2/WN3/W2 | 2.0 | 3.0 | −7 |
| 4 | WN2/WN3/W2 | 5.0 | 2.7 | −7 |
| 5 | WN4/WN5/W3 | 2.0 | 5.9 | −7 |
| 6 | WN4/WN5/W3 | 5.0 | 5.7 | −7 |

Samples 1 and 2 include a tungsten layer W1, a tungsten nitride layer WN1, and a tungsten layer W2. The tungsten layer W1 is the first layer 21; and the tungsten nitride layer WN1 is the second layer 23. The tungsten layer W2 is the third layer 25. The layer thickness of W1 of sample 1 is 1.5 nanometers (nm); and the layer thickness of W1 of sample 2 is 3.0 nm.

A sheet resistance R of the electrode 20 is 2.6 Ω/mm² and 2.8 Ω/mm² for samples 1 and 2, respectively; and the effects of the hafnium silicate are suppressed for both. However, a threshold voltage Vinv after an erasing voltage of 20 V is applied to the memory cell MC is high, i.e., −4.7 V, for sample 2; that is, it is determined that the erasing of the data is insufficient. As a result, in the case where the tungsten layer is used as the first layer 21, it is favorable for the layer thickness of the tungsten layer to be, for example, 2 nm or less. In the case where the layer thickness of the first layer 21 is, for example, less than 1 nm, it is difficult to shield the effects of the hafnium silicate. Accordingly, in the case where the tungsten layer is used as the first layer 21, it is favorable for the layer thickness of the tungsten layer to be not less than 1 nm and not more than 2 nm.

Samples 3 and 4 include a tungsten nitride layer WN2, a tungsten nitride layer WN3, and a tungsten layer W2. The tungsten nitride layer WN2 is the first layer 21; and the tungsten nitride layer WN3 is the second layer 23. The tungsten layer W2 is the third layer 25. WN3 has the first composition ratio; and WN2 has the second composition ratio having a proportion of nitrogen atoms that is smaller than that of the first composition ratio. The layer thickness of WN2 of sample 3 is 2 nm; and the layer thickness of WN2 of sample 4 is 5 nm.

The sheet resistance R of the electrode 20 is 3.0 Ω/mm² and 2.7 Ω/mm² for samples 3 and 4, respectively; and the effects of the hafnium silicate are suppressed for both. Also, the threshold voltage Vinv after the erasing voltage of 20 V is applied to the memory cell MC is −7 V for both. Thereby, it is determined that the erasing of the data also is sufficient.

In the case where the tungsten nitride layer of the first layer 21 is set to be, for example, less than 1 nm, it is difficult to shield the effects of the hafnium silicate. Accordingly, in the case where the tungsten nitride layer is used as the first layer 21, it is favorable for the layer thickness of the tungsten nitride layer to be 1 nm or more. On the other hand, the difficulty of the etching process becomes high in the case where the layer thickness of the tungsten nitride exceeds 5 nm. In other words, the process load becomes large when the total thickness of the electrode 20 becomes thick and the etching time becomes long. Accordingly, in the case where the tungsten layer is used as the first layer 21, it is favorable for the layer thickness of the tungsten layer to be not less than 1 nm and not more than 5 nm. More favorably, the layer thickness is not less than 2 nm and not more than 5 nm.

Samples 5 and 6 include a tungsten nitride layer WN4, a tungsten nitride layer WN5, and a tungsten layer W3. The tungsten nitride layer WN4 is the first layer 21; and the tungsten nitride layer WN5 is the second layer 23. The tungsten layer W3 is the third layer 25. WN5 has the first composition ratio; and WN4 has the second composition ratio having the proportion of nitrogen atoms that is smaller than that of the first composition ratio. The layer thickness of WN4 of sample 5 is 2 nm; and the layer thickness of WN4 of sample 6 is 5 nm.

The first layer 21, the second layer 23, and the third layer 25 of samples 1 to 4 are formed continuously in the same reactor. On the other hand, for samples 5 and 6, the tungsten nitride layers WN4 and WN5 are formed in a reactor separate from that of the tungsten layer W3. In other words, the tungsten nitride layers WN4 and WN5 are exposed to external air prior to forming the tungsten layer W3.

As shown in Table 1, the sheet resistance R of the electrode 20 is 5.9 Ω/mm² and 5.7 Ω/mm² for samples 5 and 6, respectively; and it can be said that the effects of the hafnium silicate are not suppressed for either. In other words, it is desirable for the first layer 21, the second layer 23, and the third layer 25 to be formed continuously without being exposed to external air. Also, a metal barrier may be inserted between the electrode 20 and the insulating layer 40. For example, tantalum nitride can be used as the metal barrier.

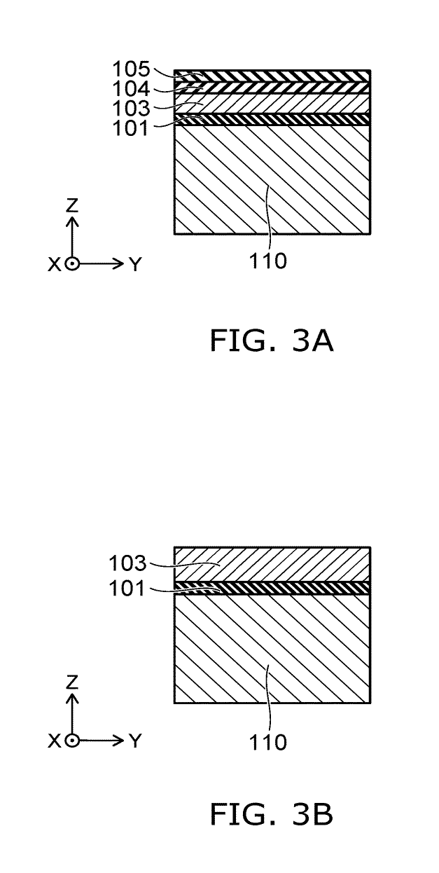

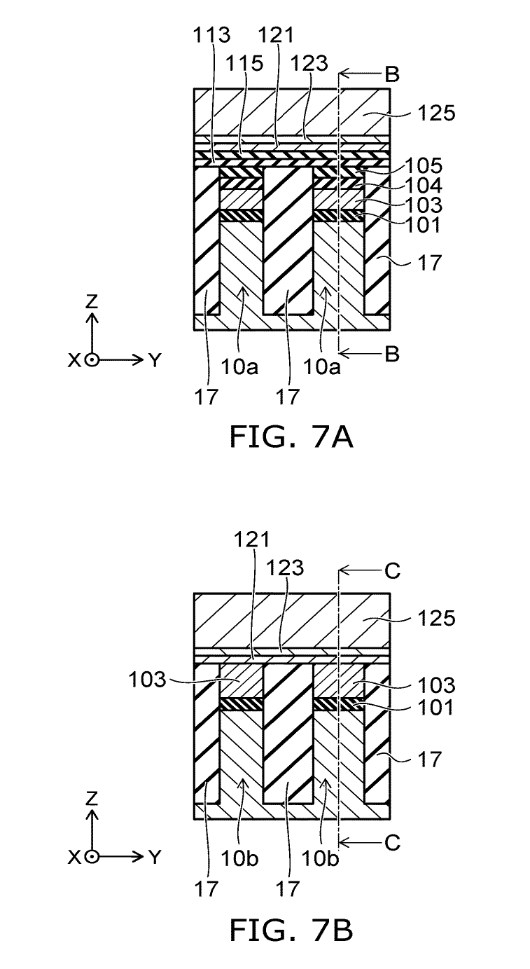

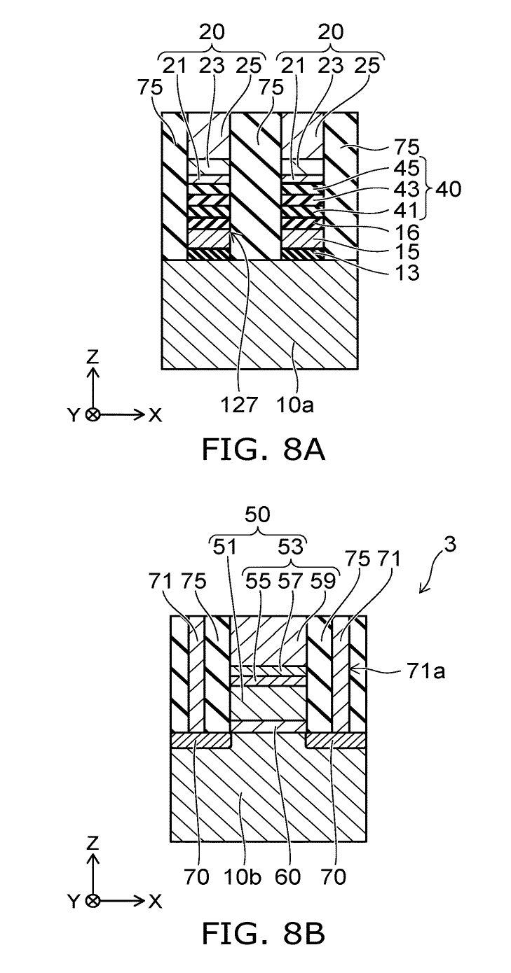

A method for manufacturing the non-volatile memory device 1 according to the first embodiment will now be described with reference to FIGS. 3A to 8B. FIGS. 3A to 8B are schematic cross-sectional views showing the manufacturing processes of the non-volatile memory device 1 in order. Each FIG. A is a cross section of the memory region MA; and each FIG. B is a cross section of the peripheral region PA. FIGS. 3A to 7B show cross sections parallel to the Y-Z plane; and FIGS. 8A and 8B respectively show cross sections along line B-B and line C-C shown in FIGS. 7A and 7B.

As shown in FIG. 3A, an insulating layer 101, a conductive layer 103, an insulating layer 104, and an insulating layer 105 are stacked in order on a semiconductor substrate 110. The semiconductor substrate 110 is, for example, a silicon substrate. The insulating layer 101 is, for example, a silicon oxide layer. The conductive layer 103 is, for example, a polysilicon layer. The insulating layer 104 is, for example, a silicon nitride layer or a silicon oxynitride layer. The insulating layer 105 is, for example, a metal oxide layer of hafnium silicate, etc.

As shown in FIG. 3B, the portion of the insulating layer 104 and the insulating layer 105 that is deposited in the peripheral region PA is selectively removed.

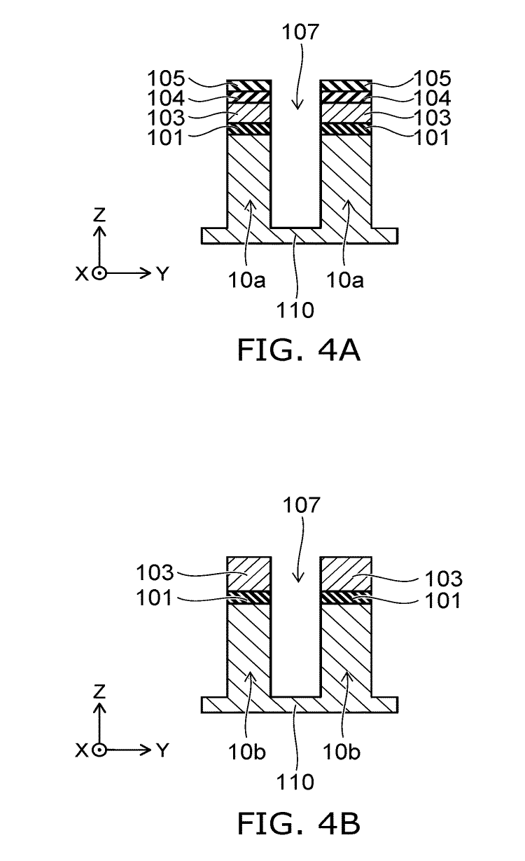

As shown in FIGS. 4A and 4B, a trench 107 is made from the upper surface of the insulating layer 105 into the interior of the semiconductor substrate 110. The trench 107 extends in the X-direction. Thereby, the semiconductor body 10a and a semiconductor body 10b are formed in the upper portion of the semiconductor substrate 110.

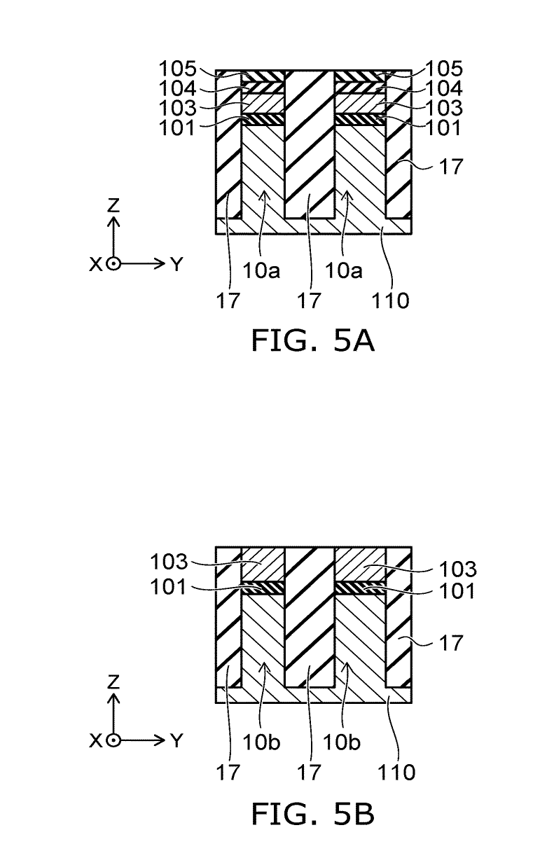

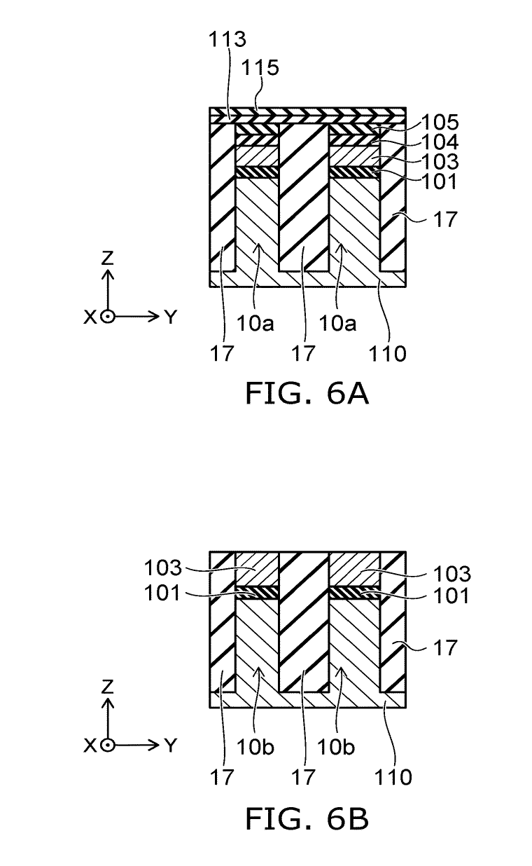

As shown in FIGS. 5A and 5B, the STI 17 is formed in the interior of the trench 107. The STI 17 is, for example, a silicon oxide layer. As shown in FIG. 6A, the upper surface of the STI 17 is formed to be positioned at the same level as the upper surface of the insulating layer 105. For example, a silicon oxide layer that fills the interior of the trench 107 and covers the insulating layer 105 is formed. Continuing, the upper surface of the insulating layer 105 is exposed by performing etch-back of the silicon oxide layer. As shown in FIG. 5B, the conductive layer 103 is exposed in the peripheral region PA.

As shown in FIG. 6A, an insulating layer 113 and an insulating layer 115 are formed in order. The insulating layer 113 includes, for example, silicon. The insulating layer 115 is, for example, a metal oxide layer of hafnium silicate, etc. As shown in FIG. 6A, the insulating layers 113 and 115 cover the surface of the insulating layer 105 and the surface of the STI 17. As shown in FIG. 6B, the insulating layers 113 and 115 that are formed in the peripheral region PA are removed.

As shown in FIG. 7A, a first metal layer 121, a second metal layer 123, and a third metal layer 125 are formed on the insulating layer 115. Also, as shown in FIG. 7B, the first metal layer 121, the second metal layer 123, and the third metal layer 125 are directly formed on the conductive layer 103 and the STI 17 in the peripheral region PA. The first metal layer 121 is, for example, a tungsten layer or a tungsten nitride layer. The second metal layer 123 is, for example, a tungsten nitride layer. The metal layer 125 is, for example, a tungsten layer.

The tungsten nitride layer that is included in the second metal layer 123 has the first composition ratio. The tungsten nitride layer that is included in the metal layer 121 has the second composition ratio having the proportion of nitrogen atoms that is smaller than that of the first composition ratio. Also, the first metal layer 121, the second metal layer 123, and the third metal layer 125 are formed using, for example, sputtering or CVD (Chemical Vapor Deposition). For example, the first metal layer 121, the second metal layer 123, and the third metal layer 125 are formed continuously in the same reactor. Also, even in the case where these layers are formed in different reactors, it is desirable for the transfer of the wafer between the reactors to be performed at reduced pressure.

FIG. 8A is a cross-sectional view along line B-B shown in FIG. 7A. As shown in FIG. 8A, a trench 127 that divides the stacked body formed on the semiconductor body 10a into a stripe configuration extending in the Y-direction is made; and an insulating layer 75 is filled into the interior of the trench 127. For example, the trench 127 is made to a depth from the upper surface of the third metal layer 125 to the semiconductor body 10a. Also, the trench 127 may be made to a depth from the upper surface of the third metal layer 125 to the insulating layer 101. In other words, the insulating layer 101 may not be divided by the trench 127. The insulating layer 75 is, for example, a silicon oxide layer.

Thereby, the multiple insulating layers 13, the multiple charge storage layers 15, the multiple insulating layers 40, and the multiple electrodes 20 are formed on the semiconductor body 10a. The insulating layers 13 are the insulating layer 101 that is mutually-separated by the trenches 107 and 127. The charge storage layers 15 are the conductive layer 103 that is mutually-separated by the trenches 107 and 127. The insulating layers 16 are the insulating layer 104 that is mutually-separated by the trenches 107 and 127. The first layers 41 of the insulating layers 40 are the insulating layer 105 that is mutually-separated by the trenches 107 and 127. The second layers 43 and the third layers 45 are the insulating layers 113 and 115 that are mutually-separated by the trench 127 and extend in the Y-direction.

The electrodes 20 are separated from each other by the trench 127 and include the first layer 21, the second layer 23, and the third layer 25 extending in the Y-direction. The first metal layer 121 is divided into the first layer 21; the second metal layer 123 is divided into the second layer 23; and the third metal layer 125 is divided into the third layer 25.

A transistor element 3 is formed in the peripheral region PA. FIG. 8B is a cross-sectional view showing the transistor element 3 along line C-C shown in FIG. 7B.

The transistor element 3 includes a gate electrode 50, a gate insulator layer 60, and source/drain regions 70. The gate insulator layer 60 is formed on the semiconductor body 10b. The gate insulator layer 60 is a portion of the insulating layer 101. The gate electrode 50 is formed on the gate insulator layer 60.

For example, the conductive layer 103, the first metal layer 121, the second metal layer 123, and the third metal layer 125 that extend in the X-direction are etched into the configuration of the gate electrode 50. Continuing, the source/drain regions 70 are formed on two sides of the gate electrode 50 in the X-direction. For example, the source/drain regions 70 are formed on the two sides of the gate electrode 50 by performing ion implantation of an n-type impurity into the semiconductor body 10b.

Further, the insulating layer 75 that covers the source/drain regions 70 is formed. Then, contact holes 71a are made from the upper surface of the insulating layer 75 to the source/drain regions 70; and contact plugs 71 are formed inside the contact holes 71a.

The gate electrode 50 includes a first electrode layer (hereinbelow, a conductive layer 51) and a second electrode layer (hereinbelow, a metal layer 53). The conductive layer 51 is a portion of the conductive layer 103 and is formed simultaneously with the charge storage layer 15. The metal layer 53 includes a first layer 55, a second layer 57, and a third layer 59. The first layer 55 is a portion of the first metal layer 121. The second layer 57 is a portion of the second metal layer 123. The third layer 59 is a portion of the third metal layer 125. In other words, the metal layer 53 has the same layer structure as the electrode 20.

In the transistor element 3, the metal layer 53 is formed directly on the conductive layer 51. The first layer 55 and the second layer 57 function as barrier layers; and interactions between the metal layer 53 and the conductive layer 51 are suppressed. For example, in the case where the conductive layer 51 is polysilicon, the reactions between the metal atoms of the third layer 59 and the silicon atoms of the conductive layer 51 (e.g., siliciding) can be suppressed.

FIGS. 9A and 9B are SEM images showing an example of the gate electrode 50. FIG. 9A shows a cross section of the gate electrode 50; and FIG. 9B shows the surface of the gate electrode 50. The metal layer 53 includes a tungsten layer as the first layer 55, includes a tungsten nitride layer as the second layer 57, and includes a tungsten layer as the third layer 59. The conductive layer 51 is a polysilicon layer.

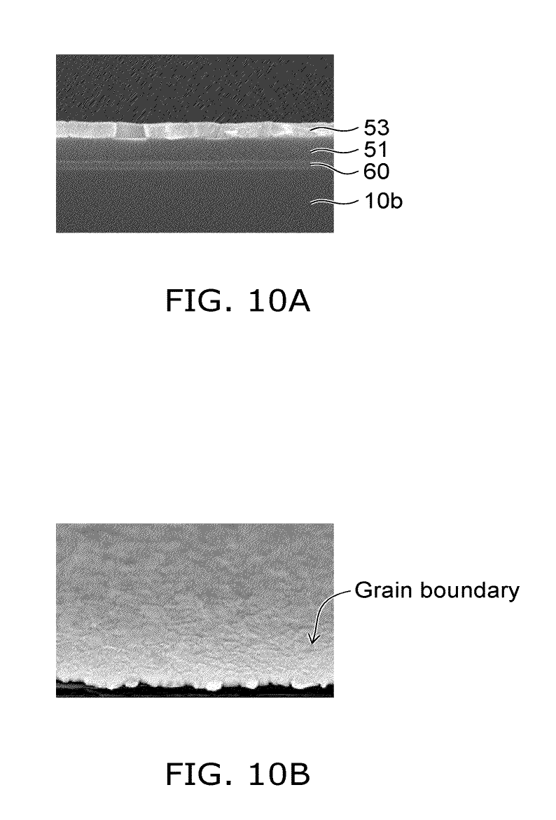

FIGS. 10A and 10B are SEM images showing another example of the gate electrode 50. FIG. 10A shows a cross section of the gate electrode 50; and FIG. 10B shows the surface of the gate electrode 50. The metal layer 53 includes tungsten nitride layers as the first layer 55 and the second layer 57 and includes a tungsten layer as the third layer 59. The composition ratio of the tungsten nitride of the first layer 55 has a proportion of nitrogen atoms that is smaller than that of the composition ratio of the tungsten nitride of the second layer 57. The conductive layer 51 is a polysilicon layer.

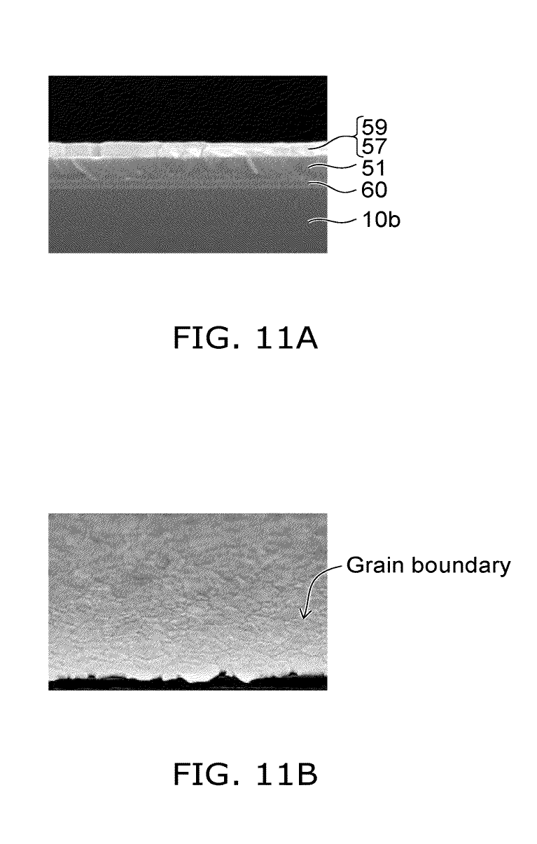

As shown in FIGS. 9A and 10A, disorder that indicates interactions at the interface between the metal layer 53 and the conductive layer 51 is not observed. Also, as shown in FIGS. 9B and 10B, unevenness does not occur in the surface of the gate electrode 50 other than at the grain boundaries. Compared to the gate electrode shown in FIGS. 11A and 11B as well, an abnormality is not observed. Also, there are no abnormalities such as peeling at the interface between the metal layer 53 and the conductive layer 51, etc. Thus, by inserting the first layer 55 and the second layer 57, a uniform interface can be maintained between the metal layer and the conductive layer 51.

FIGS. 11A and 11B are SEM images showing a gate electrode according to a comparative example. FIG. 11A shows a cross section of the gate electrode; and FIG. 11B shows the surface of the gate electrode. In the example, the metal layer includes the second layer 57 and the third layer 59 but does not include the first layer 55. The second layer 57 is a tungsten nitride layer; and the third layer 59 is a tungsten layer. The conductive layer 51 is a polysilicon layer.

Comparing FIG. 9B and FIG. 11B, it can be seen that the particle size of the third layer 59 can be increased by inserting the tungsten layer as the first layer 55. Also, comparing FIG. 10B and FIG. 11B, the particle sizes are substantially the same. In other words, it can be seen that by inserting the first layer 55, the particle size of the third layer 59 can be increased or at least the particle size can be maintained.

In the embodiment as recited above, the interconnect resistance of the electrode 20 can be reduced by forming the electrode 20 on the blocking insulating layer including the metal oxide layer, where the electrode 20 includes the first layer 55 and the second layer 57 that shield the crystal orientation of the metal oxide layer. Also, the first layer 55 and the second layer 57 function as barrier layers between the conductive layer 51 and the metal layer 53 of the transistor element 3. Accordingly, it is possible to simultaneously form the electrode 20 and the gate electrode of the transistor element 3; and the manufacturing processes of the non-volatile memory device 1 are not increased by using the electrode 20.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A non-volatile memory device, comprising:
a first semiconductor body extending in a first direction;
an electrode extending in a second direction intersecting the first direction;
a charge storage layer provided between the first semiconductor body and the electrode; and
a first insulating layer provided between the electrode and the charge storage layer,
the electrode including a first layer, a second layer, and a third layer, the first layer being provided on the first insulating layer and including tungsten; the second layer being provided on the first layer and including tungsten nitride; and the third layer being provided on the second layer and including tungsten.

2. The non-volatile memory device according to claim 1, wherein
the second layer includes a first tungsten nitride having a first composition ratio, and
the first layer includes a second tungsten nitride having a second composition ratio,
wherein a proportion of nitrogen atoms in the second composition ration is smaller than a proportion of nitrogen atoms in the first composition ratio.

3. The non-volatile memory device according to claim 2, wherein the first layer has a thickness of 2 to 5 nanometers.

4. The non-volatile memory device according to claim 1, wherein the first layer is a tungsten layer having a thickness of 1 to 2 nanometers.

5. The non-volatile memory device according to claim 1, wherein the first insulating layer includes a metal oxide.

6. The non-volatile memory device according to claim 1, wherein the first insulating layer includes a hafnium silicate.

7. The non-volatile memory device according to claim 1, wherein
the electrode contacts the first insulating layer, and
the first insulating layer includes a hafnium silicate in a portion thereof which contacts the electrode.

8. The non-volatile memory device according to claim 1, further comprising a barrier layer between the first insulating layer and the electrode.

9. The non-volatile memory device according to claim 1, further comprising a tantalum nitride layer between the first insulating layer and the electrode.

10. The non-volatile memory device according to claim 1, further comprising:
a second semiconductor body arranged in the second direction with the first semiconductor body, the second semiconductor body extending in the first direction; and
a second insulating layer provided between the first semiconductor body and the second semiconductor body,
a top surface of the second insulating layer being positioned at a level higher than a top surface of the charge storage layer.

11. The non-volatile memory device according to claim 1, further comprising a circuit including a transistor element provided around a region where the charge storage layer is disposed, the transistor element having a gate electrode that includes a first electrode layer and a second electrode layer provided directly on the first electrode layer, wherein
the first electrode layer includes polysilicon, and
the second electrode layer has the same layer structure as the electrode.

12. The non-volatile memory device according to claim 1, wherein the charge storage layer includes a layer that includes polysilicon.

13. The non-volatile memory device according to claim 12, wherein the charge storage layer further includes a silicon nitride layer or a silicon oxide layer provided between the first insulating layer and the layer including polysilicon.

14. A method for manufacturing a non-volatile memory device, the method comprising:
continuously forming a first layer, a second layer, and a third layer on a wafer without exposing to external air,
wherein the wafer includes a first semiconductor body extending in a first direction, a conductive layer provided on the first semiconductor body, and an insulating layer provided on the conductive layer, and
wherein the first layer including tungsten, the second layer including tungsten nitride, and the third layer including tungsten.

15. The method according to claim 14, wherein the first layer, the second layer, and the third layer are formed continuously inside the same reactor.
